(19) United States
(12) Patent Application Publication
(10) Pub. No.: US 2012/0273019 A1
(43) Pub. Date: Nov. 1, 2012

(54) METHOD FOR RECLAIMING ENERGY IN SMELTING SYSTEMS AND SMELTING SYSTEM BASED ON THERMOCOUPLES

(75) Inventors: Jürgen Seidel, Kreuztal (DE); Markus Finck, Dusseldorf (DE)

(73) Assignee: SMS SIEMAG AKTIENGESELLSCHAFT, Dusseldorf (DE)

(21) Appl. No.: 13/505,203

(22) PCT Filed: Oct. 25, 2010
(86) PCT No.: PCT/EP2010/066055

§ 371 Date: Jul. 23, 2012

(30) Foreign Application Priority Data
Oct. 28, 2009 (DE) 10 2009 051 095.8
Feb. 2, 2010 (DE) 10 2010 006 695.8
Feb. 20, 2010 (DE) 10 2010 008 728.9
Sep. 2, 2010 (DE) 10 2010 036 188.7

(51) Int. Cl. H01L 35/28

(52) U.S. Cl. 136/201; 136/205

(57) ABSTRACT

The invention relates to a method for reclaiming energy in smelting systems by utilizing residual heat of a system component and/or a warm product (1). In order to be able to reclaim energy in a technically simple manner at a good level of efficiency, according to the invention, a heat flow (dQ/dt) is allowed to flow from a system component and/or warm product (1) having a first temperature level (T₁) to a location having a second, lower temperature level (T₂), wherein a thermocouple (2) is disposed in the area between the two temperature levels (T₁, T₂), by means of which electrical energy is obtained directly, utilizing the heat flow (dQ/dt). The invention further relates to a smelting system.

The invention relates to a method for recuperating energy in metallurgical plants comprising a continuous casting plant and/or a furnace and/or a hot strip rolling train, by utilizing residual heat of a plant part or product. Moreover, the invention relates to a metallurgicaa plant.

In the metallurgical field, i.e., in steel production, aluminum production and nonferrous metal production, large quantities of waste heat are produced as a result of the process, for example, in smelting pig iron or directly reduced iron sponge in the manufacture of pig steel (“fining,” in the converter process), and in the complex manipulation of media (cooling water). The metallurgical products also frequently contain a large heat quantity.

In particular, this applies to continuous casting plants and hot strip rolling trains, in particular in the production and processing of slabs into strips or into coils, wherein the heat quantity released when cooling the cast strand as well as the slabs, billets and/or coils, is wasted.

When cooling the steel from about 1,570° C. (liquid) to an average temperature of about 1,200° C. as it runs out of the continuous casting plant, about 145 kWh/t heat energy is removed. This heat in most cases is lost to the surroundings (air and cooling water).

In hot strip rolling plants, after casting, the residual heat of the slab has been utilized in such a way that the slabs are either directly rolled or placed warm or hot into the furnace. This makes it possible to save a large quantity of heat. A requirement for the hot or direct use is that a continuous casting plant and slab furnace is located in the local vicinity. However, in older plants this is not always available. For reasons of logistics, surface testing, rolling program planning, etc., only a portion of the production is further processed directly or in the hot state. Accordingly, normally the slabs cool after casting in a shed through which air is conducted and are stacked prior to their further transport. The same is true for the residual heat which is present in the coils after coiling, which frequently cool in the air.

The efficiency of a metallurgical plant depends to a great extent on its energy consumption. A savings of the energy used, but also the recuperation of the residual heat, can improve the efficiency of a plant.

In the complex process of steel production, residual heat quantities are wasted in various process steps. They are characterized, on the one hand, through their heat contents per unit of time, i.e., in the heat flow and, on the other hand, through the temperature at which the process takes place or its energy can be captured usably. Simultaneously, for utilizing the energy, a thermal trough with low temperatures must be available.

The great band width of residual heat sources requires scalable units which have a sufficient efficiency for facilitating its use even at temperatures at a lower temperature level.

The residual heat utilization, by converting heat into electric energy or utilizing the process heat, is increasingly carried out in the metal, cement or glass industries, which are very energy intensive.

Also, in the field of steel production it is known from WO 2008/07870 A1 in the manufacture of liquid iron, to transfer the waste heat generated by reduction in a fluidized bed reactor to high pressure steam production, in which then for example, a steam turbine is operated for current production.

EP 0 044 957 B1 describes a plant for returning the latent and discernible heat of waste gasses from a cupola furnace for cast iron production or a similar smelting device, for the purpose of obtaining electrical and/or thermal energy in the form of steam and/or hot water. The plant consists of a thermal unit with a burner and two waste vessels through which the smoke gasses flow, as well as in the production of electrical energy in addition to a turbine fed by steam and an alternating current generator.

From DE 26 22 722 C3 a device for cooling hot steel slabs following the last rolling procedure, in which the steel slabs are placed on edge between vertical support columns arranged in parallel rows. The heat radiating from the steel slabs is absorbed by cooling walls arranged between the support columns with tube bundles through which cooling water flows and is utilized for steam production.

EP 0 027 787 B1 describes a plant for capturing the discernible heat from slabs by the continuous casting plant in a cooling chamber by means of air which is brought in direct contact with the slab surfaces by means of a blower. The air heated in this manner then serves outside of the cooling chamber as a heat medium, particularly for a circulation medium conducted in a thermodynamic circulation process.

EP 1 965 446 A1 and WO 2005/104156 A2 disclose thermoelectric modules as such, as well as their manufacturing methods.

In spite of the large heat quantities that are generated in the metallurgical field, its utilization is still frequently not economical. On the one hand, the energies have in many cases a temperature which is too low, on the other hand, its utilization requires also presence of a “cold side,” since any circulation process for recuperating energy requires a thermal drop (ΔT=T₀−Tᵤ). At a given heat flow dQ/dt, the usable output P computes to P=η dQ/dt, wherein η is the efficiency of the total process.

The efficiency is limited by the Carnot efficiency of the ideal circulation process which computes to η=(1−(Tᵤ/T₀)). In this connection, the temperatures are to be inserted in Kelvin.

The higher the process temperature T₀, the higher also is the Carnot efficiency. The efficiency of the circulation process generally is an approximate constant fraction of the Carnot efficiency. Circulation processes for energy production can be configured with various units, for example, evaporator, turbine and return cooling, as shown by the above examples. Water serves as the heat conducting medium.

Accordingly, existing solution attempts for heat recuperation in metallurgical plants are based on classical circulation processes, i.e., heat conduction medium is, for example, conducted over a steam turbine which, in turn, drives a generator. A classical medium for these purposes is water, however, in special cases, low boiling hydrocarbon compounds may also be used (so-called ORC-Organic Rankine Cycle).

The efficiency of such a solution increases with the size of the plant. This limits the scalability of such a solution. An ORC-based plant becomes economical only starting at a certain size and thus, starting with a certain investment volume. In contrast, thermocouple elements can be used in the case of smaller heat sources. The necessary investment costs are virtually proportional to the installed electrical output. The efficiency is almost independent, of the size.

Additional disadvantages in the use of the ORC method are the additionally required heat transport medium as well as its temperature resistance (as of today, about 320° C.) In addition, this attempt includes a significant number of additional units.

The present invention is based on the object of proposing a method and a device for energy recuperation in metallurgical plants by utilizing residual heat of a plant part or a hot product, which make it possible to achieve a sufficient efficiency, wherein the plant can easily and optimally be adapted to the given size conditions of the metallurgical plant. In this connection, an economical conversion should be possible. Accordingly, especially a method and a plant for the efficient energy recuperation of the cooling heat of a continuous casting plant as well as the residual heat of slabs and coils which are present in a hot strip rolling train, are to be proposed.

The solution of this object, is characterized by a method in which a heat flow is allowed to flow from a plant part or a hot product having a first temperature level to a location with a second, lower temperature level, wherein, in the area between the two temperature levels at least one thermocouple element is arranged by means of which electrical energy is produced directly by utilizing the heat flow.

Preferably to be used as a thermocouple element is an element with at least one doped pair of semiconductors. Moreover, to be used as a thermocouple element is an element which has been made by means of the PVD method (Physical Vapor Deposition). In this case, preferably a number of thermocouple elements are switched together to form a thermocouple electric generator (TEG). It is preferably provided in this regard that initially a slab is cast in the continuous casting plant, and that following the continuous casting plant the slab is cut to length by means of a severing device, particularly a flame cutting machine, wherein the slab is protected before and/or behind the severing device against the removal of heat by thermal insulation means. In this case, thermal insulation means constructed as a thermal insulation hood can be positioned in such a way that its location is adapted to the actual slab size and/or to the conditions when cutting the slab to length.

The cut slab can then be transported to slab storage, wherein the transport takes place through a roller table which is surrounded at least partially by thermoelectric generators. The slab can be transported in the longitudinal or transverse direction and allowed to cool between the continuous casting plant and the slab storage in such a way that it reaches a predetermined temperature, or does not drop below a predetermined temperature.

The at least one segment of a thermoelectric generator or thermocouple element is preferably cooled on at least one side. This side constitutes the thermal trough in the energy recuperation process.

Another further development of the method advantageously provides that the cooling heat is utilized on the cold side of the thermocouple element for another process, than for the one for which the heat is required. In this connection, the cooling heat is preferably used for drying a substance, seawater desalination, heating a device, or for chemical processes.

The metallurgical plant comprising a continuous casting plant and/or a furnace and/or a hot strip rolling train which has a plant part or a hot product at a first temperature level and a location having a second, lower temperature level is distinguished by the fact that during operation in the area between the plant part or product with the first temperature level and the location with the second temperature level, at least one thermocouple element is arranged which is suitable for the direct production of electrical energy by utilizing the heat flow resulting from the temperature gradient.

The thermocouple element preferably has at least one doped semiconductor pair. It preferably includes a silicon wafer which has been coated by means of the PVD method (Physical Vapor Deposition) and subsequently processed mechanically. Preferably a number of thermocouple elements are switched together to a thermoelectric generator (TEG).

Already during the casting in the continuous casting plant, thermocouple elements or thermoelectric generators (TEG) can be mounted between and/or next to the strand rollers.

When transporting the products on a transport path particularly a roller table on which no thermocouple element is arranged, the transport path may be provided with heat insulation means.

Alternatively, a transport path, particularly a roller table for the transported product, may be provided with thermocouple elements or thermoelectric generators for the production of current.

When heating or reheating the products (for example, slabs) in a furnace, the hot combustion air escapes through the waste gas duct. Within the waste gas duct or/and the pipe or duct wall, thermal generator modules are provided for converting the exhaust heat into electrical energy. This system is also combined, with the heating of the furnace air.

The plant may include a slab and/or coil storage, whose walls have thermocouple elements and/or heat insulation means. The thermocouple elements and/or the thermoelectric means and/or thermo-insulation means may be movable, particularly pivotable or translatory slidable. Moreover in the storage, further air revolving means may be arranged, particularly at least a blower.

The slab storage and/or coil storage may also be constructed as a holding pit.

Preferably, cooling means are arranged for cooling at least one side of the thermocouple element.

Even though, compared to plants in which a thermodynamic circulation process takes place, thermocouple elements are based on a completely different operating principle, their efficiency is also limited by the Carnot efficiency.

Conventional thermocouple elements have been built and used since the 1950's. They are based on the so-called Seebeck effect which can be used technically when two electrical conductors are brought into contact with each other and are subjected to a temperature gradient. An electrical voltage is generated. A continuously applied heat flow then produces an electrical energy.

Although thermocouple elements have been known for a long time, they are still not widely used in the production of electricity. A reason for this is their relatively small efficiency in conventional construction and their cost intensive manufacture.

In recent times the development of thermocouple elements has made significant progress which seems to make their technical applicability much more attractive. Thermocouple elements of the newest generation are produced on the basis of doped semiconductor pairings. The production processes have been significantly improved and are based on efficient methods as they are known from mass production of computer chips.

Silicon wafers are used which are coated by means of the PVD method (Physical Vapor Deposition) and are subsequently mechanically processed. The elements produced in accordance with this method achieve an output yield many times better than previously, with more favorable manufacturing prices than thermocouple elements previously sold on the market.

For energy production on a technically relevant scale, a plurality of thermocouple elements are switched together to form a thermoelectric generator (TEG).

Assuming a sufficiently usable efficiency, thermocouple elements provide a solution for the above-explained size problem. Thermocouple elements can be switched together without problems into large units without having a negative influence on the efficiency. Consequently, the units to be manufactured can be adapted precisely to the heat flow to be utilized in the respective process step.

A solution according to the prior art on the basis of steam turbines or generally of a Rankine circular process offers a significantly lower flexibility. In addition, there is the problem of the heat conducting medium as well as the movable parts of the heat recuperation plant. Thermocouple elements, on the other hand, are capable of producing electric energy directly without requiring an additional unit. The omission of a heat conducting medium also fundamentally increases the efficiency because the Carnot efficiency can be generally higher.

Consequently, the proposed solution makes it possible to construct a plant which is precisely tailored to the respective use, facilitates the use of thermocouple elements in a metallurgical plant, and fully realizes the advantages of the plant. It is made possible to utilize a heat flow efficiently and to transfer it to the thermocouple elements. Also important is an efficient re-cooling, particularly by using already existing plant components (for example a cooling cycle). Independently of the concrete location of use, these units can be constructed very differently. The construction may be scalable. A modular construction is an apparent solution.

In accordance with a preferred embodiment of the invention, the cast strand or slab is transported in the direction of the rolling train or to slab storage and subsequently into a coil storage, wherein heat is removed during casting and/or transportation. The slabs or coils can be deposited partially one above the other on specially prepared storage places equipped with TEG modules for a short time or for several hours or for days, wherein during this transportation period residual heat is transferred to the cast strand and/or the slab and/or during the storage period to the TEG modules for the generation of current. These plant areas are distinguished by continuously making available the heat and by a high energy density and, thus, high current generating high efficiency.

The above-mentioned TEG elements produce currents directly. The TEG elements are particularly suitable because the energy efficiency and the production techniques have in recent times been significantly improved as compared to the traditionally manufactured elements. The attainable efficiencies are certainly comparable to those of conventional technologies (for example, ORC-Organic Rankine Cycle—i.e., steam turbine process with low boiling organic medium)—in the temperature range which is relevant here, in metallurgical plants about 10%-15%. However, TEG elements do not absolutely require an external added aggregate because the current is produced directly in the immediate vicinity of the heat source, i.e., the turbine, the mechanical generator, as well as the tubing for the heat transporting medium are omitted. Only for the cold side of the thermoelectric generator, cooling with a liquid medium can be carried out instead of with air.

It is also possible to withdraw heat from the strand already during casting and to conduct this heat to the TEG module for the generation of current. For this purpose, TEG modules are preferably provided between the strand rollers.

After severing or cutting the slabs to length, the slabs are transported from the continuous casting plant as quickly as possible to the slab storage, or the coils are transported after coiling to the coil storage and are there placed on the reservoir-type storage locations equipped with the TEG modules. Also, already during their transport to the slab storage or coil storage, a partial quantity of their residual heat can be removed for which purpose the transport means leading to the reservoir-type storage locations can be constructed with thermal insulation or can be constructed with TEG modules. The transport of the slabs can, in the longitudinal direction, take place in a type of inverse roller hearth furnace or in the transverse direction in a type of inverted pushing beam or walking beam furnace. In the case of a slow transport speed and a long transport path, this type of construction constitutes a part of the slab storage with TEG modules for energy recuperation or current production.

The slab storage or coil storage can advantageously be constructed as high shelves in which the slabs or coils are inserted flat with, for example, a stacker laterally into the reservoir-type storage locations. The slabs or coils are, in this case, placed on support rails. Wall, ceiling and floor constructions are lined with TEG modules. Alternatively and particularly advantageously, the TEG modules are positioned in front of supporting walls, so that the accessibility and the simple exchangeability are available when maintenance is required. In another embodiment, the slabs are tilted and are stored on edge between TEG modules, wherein the slab storage is constructed with guide struts and/or lateral rollers in order to prevent tilting of the slabs. In such slab storage, the slabs rest only on a small number of points, for example, on rollers.

In order to ensure that the slabs or coils rest with as high a temperature as possible in the reservoir-type storage locations, an appropriate useful/optimum exchange can be carried out within the slab or coil storage.

In order to be able to carry out an unimpeded transport of the slabs or coils in and out of the reservoir-type storage locations, the TEG modules arranged above the slabs or coils are preferably constructed so as to be pivotable or slidable. Alternatively, the reservoir-type storage locations are equipped with pivotable or slidable thermally insulated insulation hoods with or without integrated TEG modules.

The production of a turbulent air flow in the heat exchanger area or within the reservoir-type storage locations, for example, by blowers or ventilators, shortens the cooling period. However, in this case, the maximum permissible cooling speed of the slabs or coils must be taken into consideration in order to prevent a reduction in quality.

A typical preferred embodiment for the arrangement of several reservoir-type storage locations next to each other is possible in the form of a holding pit. The slabs rest in the longitudinal direction on support beams. By using displaceable ceiling plates, the slab stack can be formed under the plates, or also the slabs can be removed individually after cooling. Alternatively, the ceiling plates are also individually pivotable upwardly for each reservoir type storage location. TEG modules are arranged on the floor, on the wall and optionally, also on the ceiling, as well as between the slab stacks. Instead of discharging the energy to the surroundings through a forced convection, the energy is in a targeted manner transferred to these TEG modules and current is produced.

The typical preferred method steps in the transportation of slabs and slab storage with a recuperation system for slab heat take place as follows:
a) Casting of the slab.
b) Severing the slab following the continuous casting plant to the required length (optionally also in the area of the slab storage) and with the use of thermal insulation in front of and in the area of the flame cutting machine. The insulation hoods are pivoted up in the area of the flame cutting machine, step by step, in dependence on the position of the flame and are lowered again in order to minimize heat loss in the area between the continuous casting plant and the flame cutting plant and within the flame cutting plant,
c) Transporting the slab into the slab storage on a roller table provided with TEG modules or optionally on a thermally insulated roller table with preferably increased transport speed.
d) Moving the slab onto a lifting or pushing position at casting speed or optionally at increased transport speed.
The transport in steps c) and d) is controlled with respect to time, preferably in such a way that the temperature does not drop below a necessary minimum temperature of 800° C. for storage.
e) If the lifting position is provided with thermal insulation hoods, these hoods are folded up.
f) Rapid transport of the slab to a heat exchanger location. Preferably, the slab is stacked and/or transported into a position (for example pit) surrounded by TEG modules. When stacking the slabs, the heat recuperation chamber is only briefly opened for filling with slabs.
g) Slow cooling of the slabs on the location equipped with TEG modules in which the thermal energy is captured.
h) After a predetermined time or when reaching a slab stacking temperature at a defined reference location, the slab stack is dispersed.

A process model preferably monitors and controls the cooling process wherein, especially starting from a measured or computed strand or slab temperature, cooling of the slab is computed in dependence on the ambient conditions. The longer the slab remains in the reservoir-type storage location for dissipating heat the better is the energy utilization. Thus, an individual slab loses, for example, 600° C. in fire hours. If the slab tonnage is higher than the throughput resulting from the sum of all TEG module locations, a process model shortens the storage time accordingly.

Simultaneously, the process model, combines the use of the TEG module locations in a useful manner with a storage and transport system, in order, for example, to deposit or place the slabs or coils in storage in an orderly manner and to retrieve them again selectively for further processing as required. A process model for controlling other process sequences (pumps for the cooling medium, product speed, etc.) are provided analogously, but are not further described.

The TEG modules are cooled from one side. Water is preferably used as the cooling medium for the TEG modules. However, it is also possible to use, depending on the border conditions, mineral or synthetic thermoil or gas (air, nitrogen, smoke gas, etc.) can also be used.

Depending on the temperature level of the cooling medium, it can advantageously be used for other processes such as, drying systems, district heating systems, chemical processes, seawater desalination, etc. and increase the overall efficiency of the heat recuperation device. The heat would then not be wasted and would not be fed to cooling towers.

The described technology is not limited to conventional hot strip rolling plants or CSP plants with thick slabs or thin slabs and their coils, but can also be utilized in the same manner in the production of blocks, billets, girders, or round steel, etc. This technology could be advantageous also in nonferrous heating plants (strip plants, etc.).

The TEG modules can be used individually for energy recuperation or can be combined suitably and advantageously with other energy recuperation technologies constructed preferably with an ORC plant or Kalina plant (circulation process). For example, the TEG modules are operated at high temperatures which are cooled with a cooling medium (for example thermoil) at about 300° C. This energy (or hot cooling medium) is subsequently further utilized in an ORC plant or Kalina plant for current production. An inverse arrangement is also conceivable, so that initially the high temperature waste heat is absorbed by, for example, an ORC plant, and the condenser heat exchanger of the for example, ORC plant, which transfers the low temperature heat to TEG modules.

Both devices (heat exchanger for operating an ORC plant and thermoelectric generators) can also be arranged at a location one behind the other.

In the drawings, embodiments of the invention are illustrated.

In the drawing:

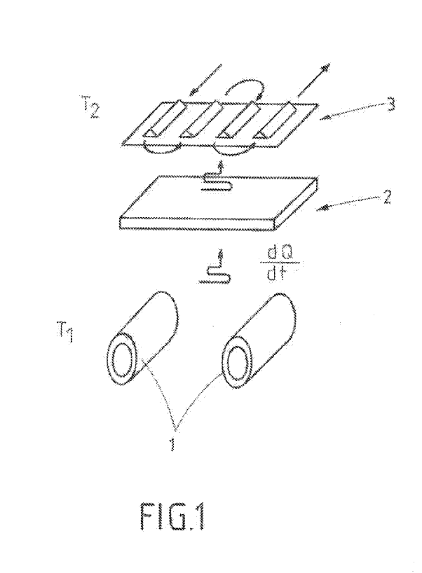

FIG. 1 is a schematic perspective view of two billets whose thermal energy is converted into electrical energy by a thermoelectric generator,

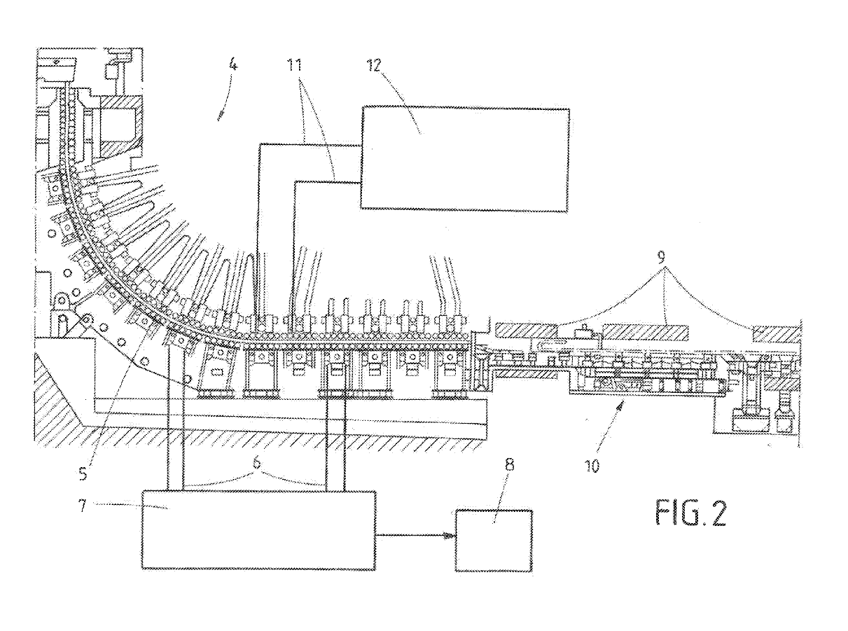

FIG. 2 is a side view of a continuous casting plant with thermoelectric generators (TEG units),

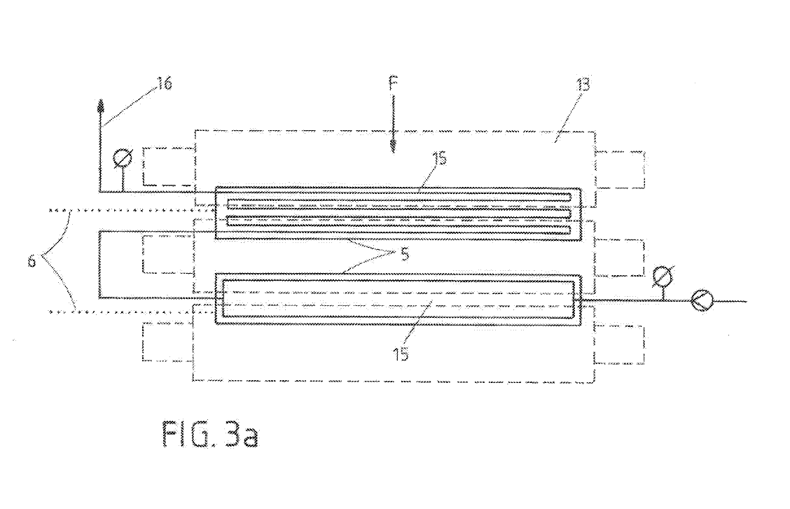

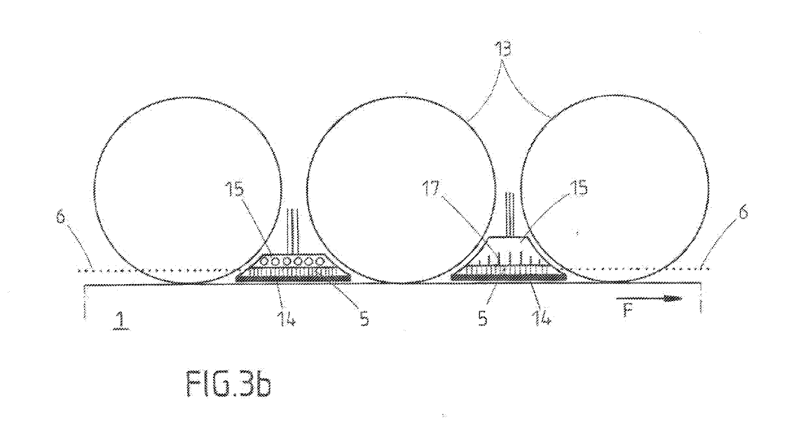

FIG. 3a is a front view, and

FIG. 3b is a side view of a section of a strand segment of the continuous casting plant with TEG modules between segment rollers of the plant,

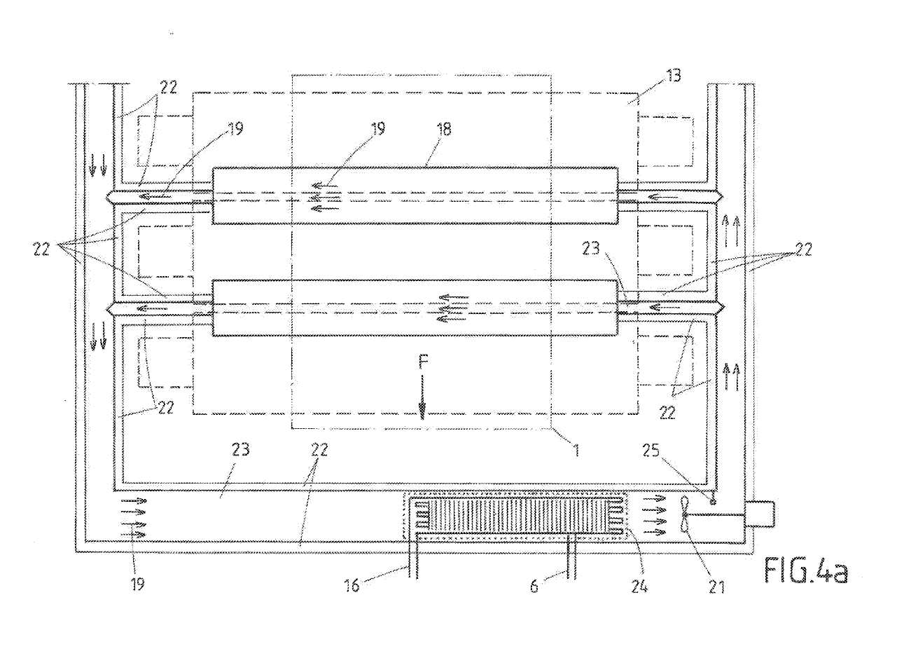

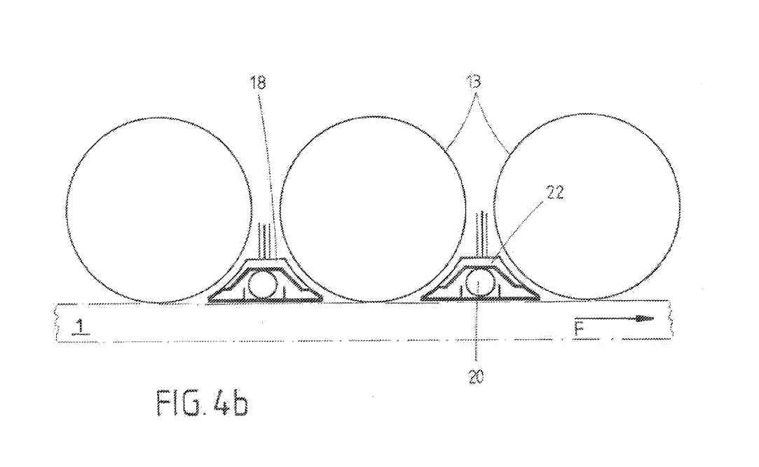

FIG. 4a is a front view, and

FIG. 4b is a side view of an alternative embodiment with TEG modules in the area of a continuous casting plant,

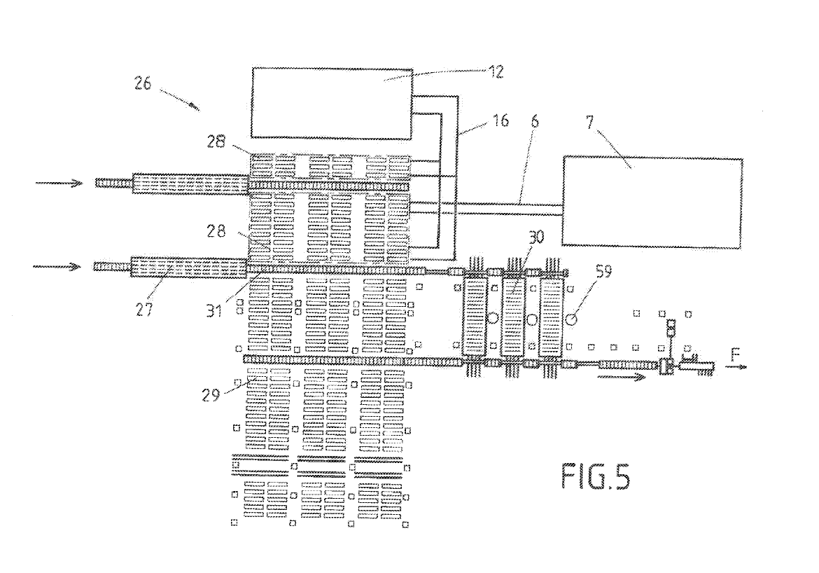

FIG. 5 is a top view of slab storage with the TEG modules in the area of the slab reservoir-type storage locations,

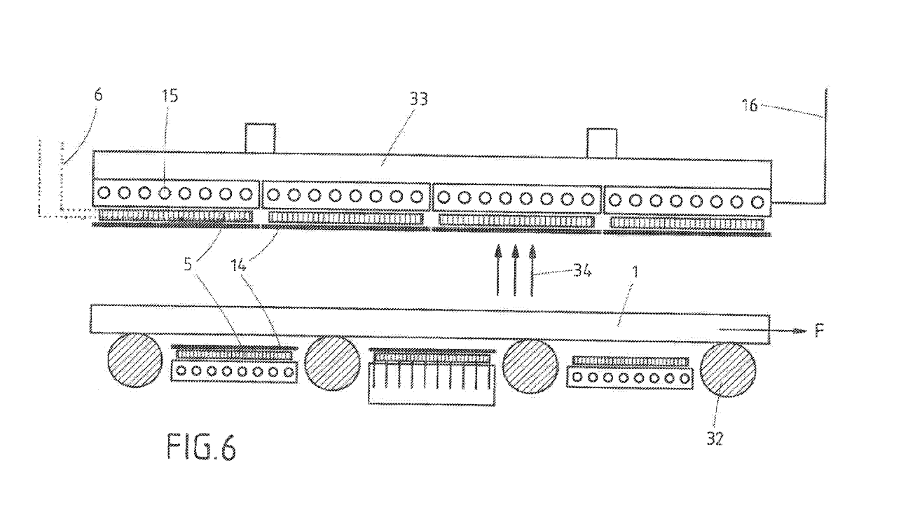

FIG. 6 is a side view of a roller table with TEG modules,

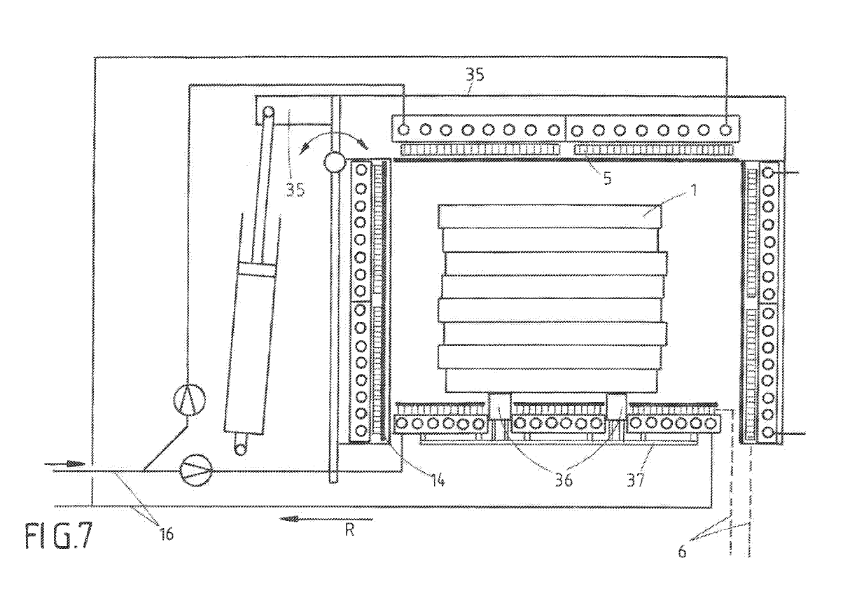

FIG. 7 is a side view of a slab reservoir-type storage location with fixed and pivotable upper TEG modules,

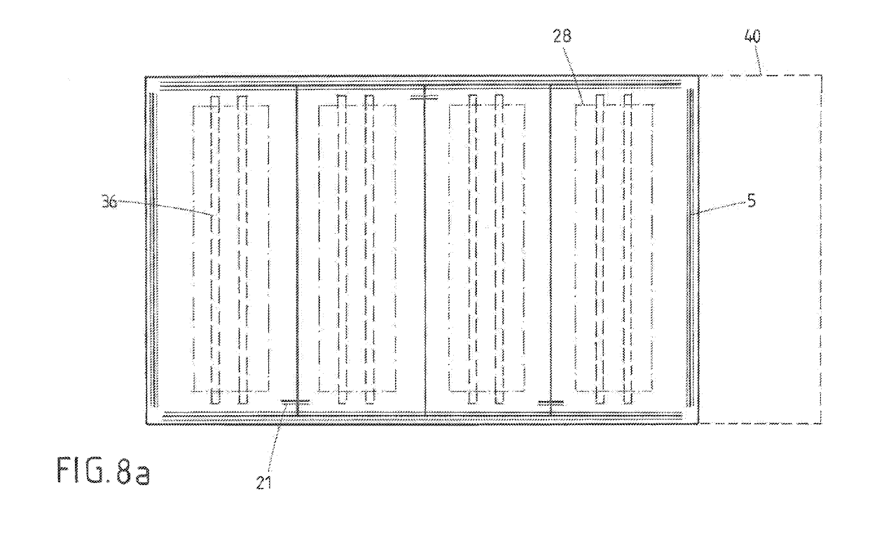

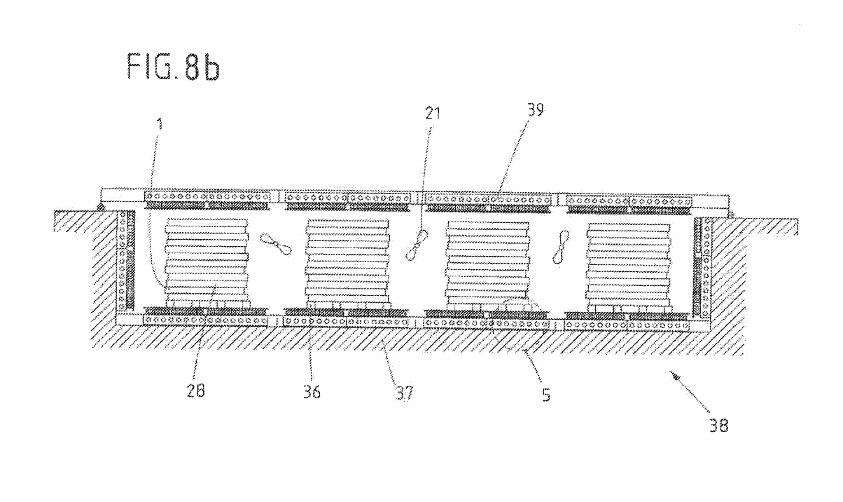

FIG. 8a is a top view, and

FIG. 8b is a side view of an arrangement of TEG modules in a holding pit,

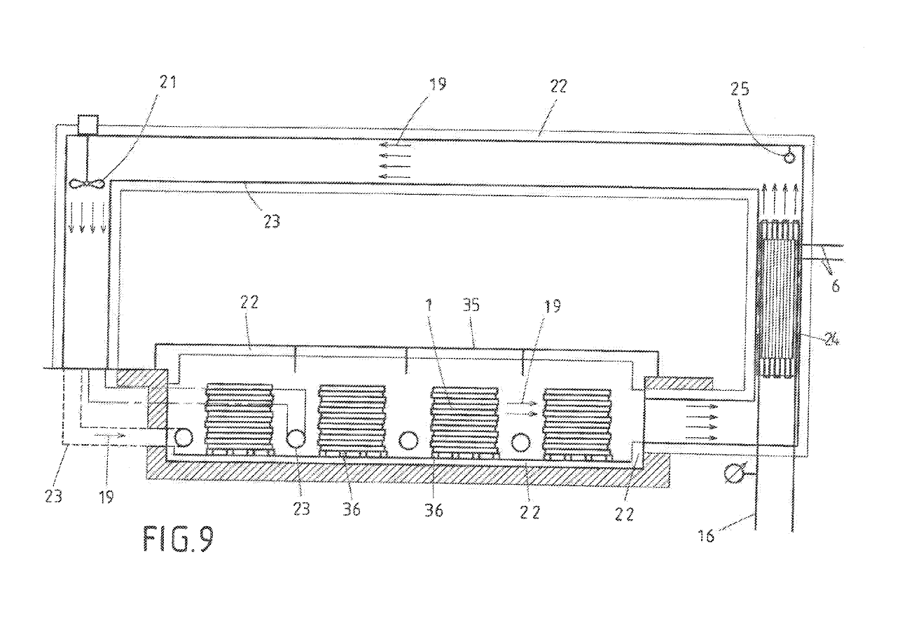

FIG. 9 is a side view of an alternative arrangement of TEG modules in the area of a holding pit,

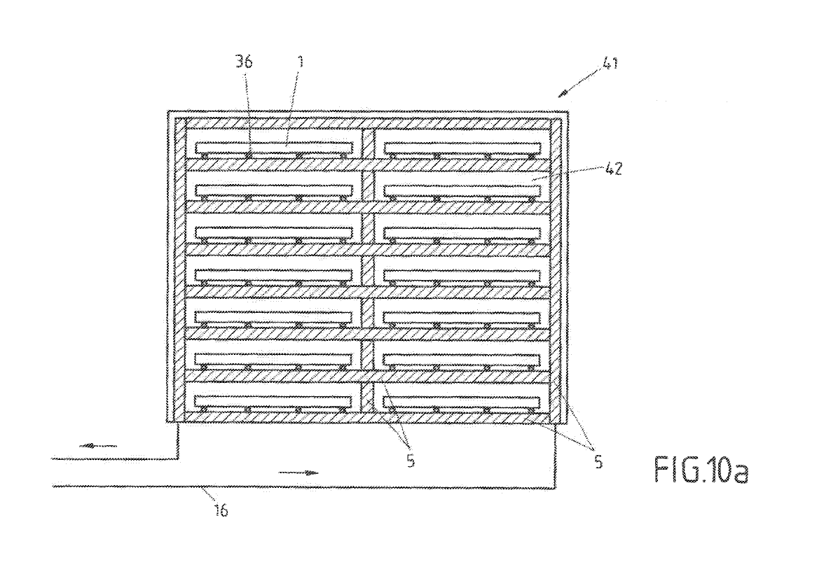

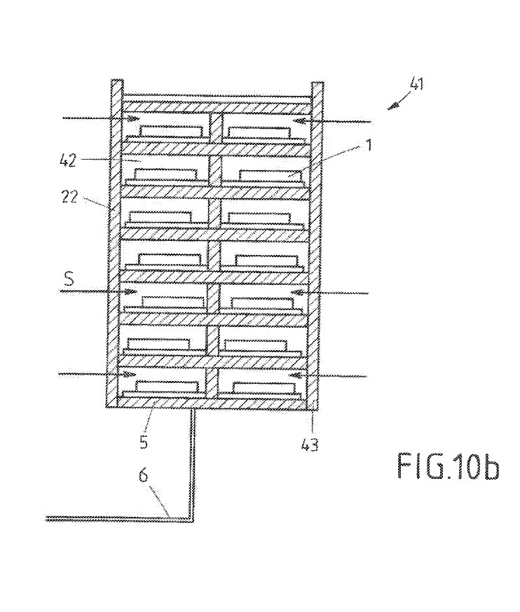

FIG. 10a is a front view, and

FIG. 10b is a side view of a high storage shelf with TEG modules,

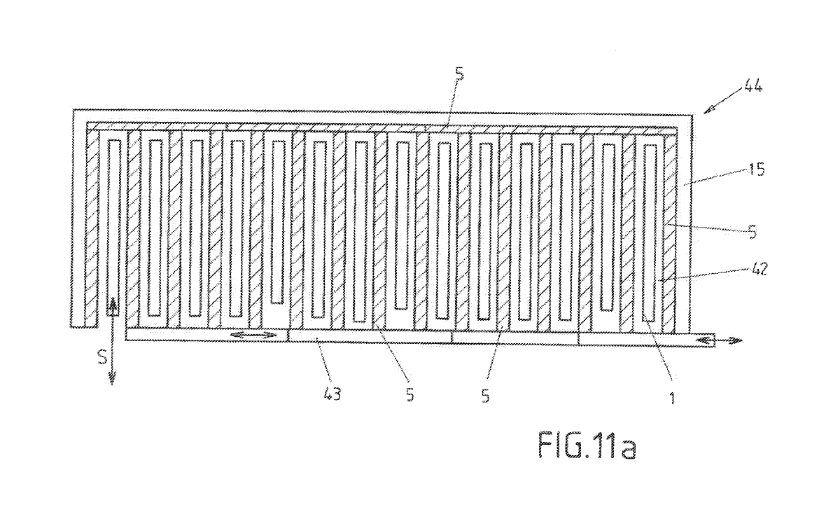

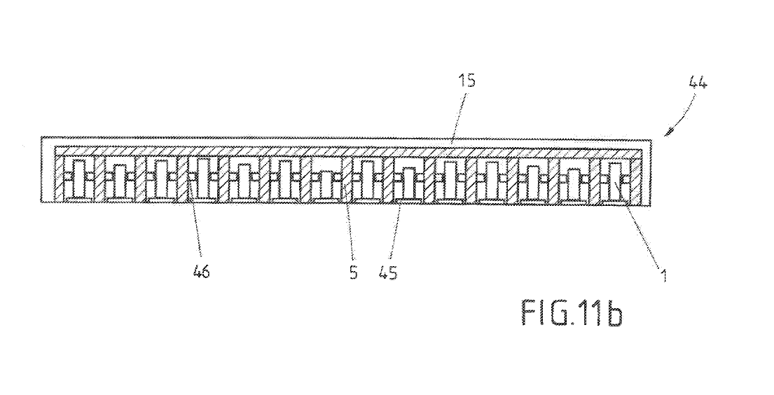

FIG. 11a is a top view, and

FIG. 11b is a front view of storage of slabs placed on edge with TEG modules,

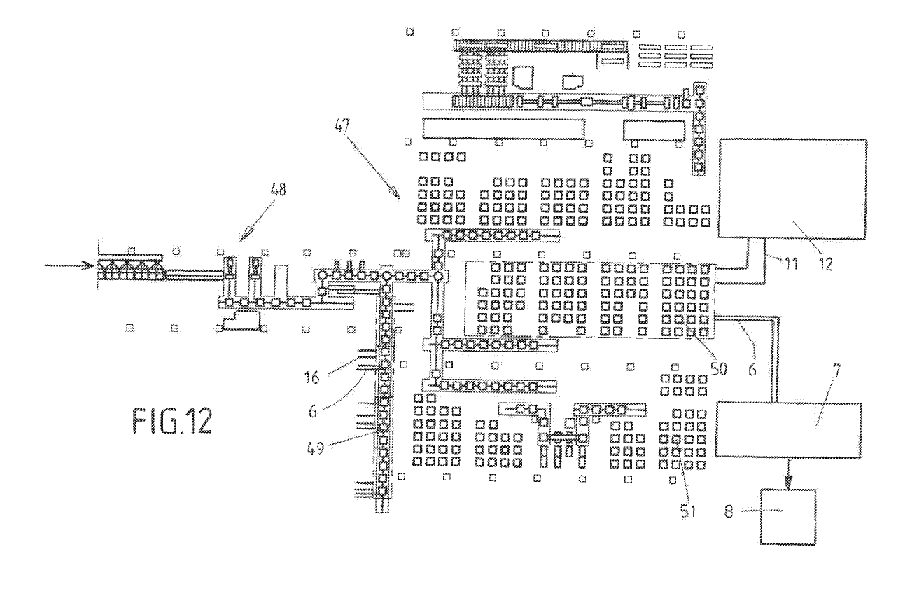

FIG. 12 is a top view of coil storage with TEG modules in the area of coil reservoir-type storage locations,

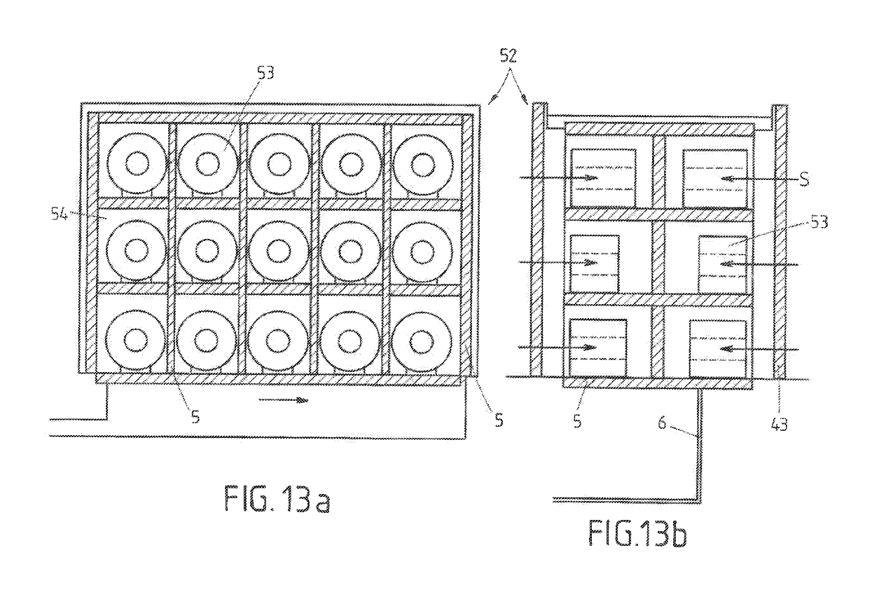

FIG. 13a is a front view, and

FIG. 13b is a side view of a high shelf for coil storage with TEG modules,

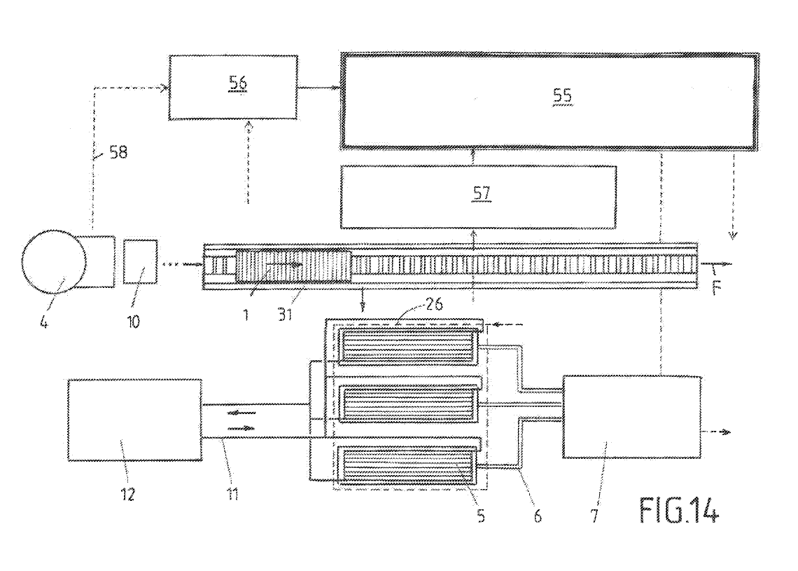

FIG. 14 schematically illustrates a process model.

Of the large number of applications, FIG. 1 shows as an example, an arrangement which utilizes the waste heat of a cast round billet on a reversible cooling bed.

In the metallurgical field many process steps produce waste heat quantities, for example, in the smelting or casting operations in converters, electric furnaces, continuous casting plants, adjusting units, and also when shaping (hot rolling train, coiler) or treating strip (annealing lines).

The heat sources characterizing a steel mill (for example, electrical arch furnace—EAF, walking beam or pusher type furnaces), which must always also be connected to a heat trough for cooling (for example, to a closed cooling water cycle), produce a heat gradient which has not been utilized up to now. It is this previously not used waste heat flow, which always exists in cooled steel and metallurgical processes, which presently and according to the invention generates energy usable by employing thermoelectric generators (TEG). By mounting thermoelectric generators between the heat source and the heat trough, electrical energy is produced based on the different temperature levels.

The heat sources differ with respect to the usable thermal flow dQ/dt as well as with respect to the process temperature T₀. Ideally, the thermoelectric generator is placed as close as possible to the heat source in order to achieve Carnot efficiency as high as possible.

A possible application of thermoelectric generators in a steel mill is to utilize the waste heat of a cast semi-finished product like a billet 1. This billet has an upper process temperature T₁.

Immediately after casting the billets 1 cool, for example, on an inverted cooling bed. In that case, their thermal energy normally radiates into the atmosphere unused. The heat flow dissipated by radiation dQ/dt is then computed for a technical radiator to

dQ/dt=σεAT₁⁴

wherein
T is the temperature in Kelvin,
σ is the Boltzmann constant,
ε is the emission coefficient, and
A is the billet surface area.

In order to utilize the discharged heat flow, a thermoelectric generator in the form of a panel is placed over the cooling bed. FIG. 1 shows two hot billets 1 above which a flat thermocouple element 2 in the form of a thermoelectric generator is arranged, wherein, in turn, above the thermocouole element 2 a water cooling 3 is arranged.

Only a fraction of the thermal flow is radiated to the thermocouple element 2. This fraction can be taken into consideration through a form factor. Since the bottom side of the thermocouple element 2 is also heated and itself emits radiation, the net thermal flow received from the thermocouple element 2 results as the difference of the thermo radiation flow of the billet 1 to the thermocouple element 2, minus the thermal flow radiated back by the thermocouple element 2 to the billet 1.

This output is essentially available to the thermocouple element 2 for converting into electrical energy.

The energy balance of the thermocouple element 2, itself, must take into consideration the heat flow conducted from the thermocouple element 2 in the direction of cooling. As already mentioned above, only a fraction of the received heat flow can be utilized. This fraction corresponds to the efficiency η.

Modern doped semiconductor materials reach about 40% of the Carnot efficiency η_{c}. By conducting heat within the thermoelectric generator 2, additionally a heat flow takes place through the individual thermocouple elements.

At a given billet temperature T₁ and a given average cooling water temperature T₂ it can be computed, on the basis of the thermodynamic relationships, that in the case of conventional number values, for the billet temperature and for the water temperature, a useful electrical power of about 2,000 W per billet results with a possible efficiency of η=10%.

In total, it can be said that the use of modern thermocouple elements for the recuperation of energy in a steel mill provides several significant advantages. In this respect, the great field of use and the high reliability are to be mentioned.

Through the further development of the thermocouple elements with respect to material use and manufacturing methods in recent times, efficiencies can be reached which significantly improve the economic operation of the plant. Moreover, the use of thermoelectric generators is possible already with a relatively small investment in apparatus.

FIG. 2 shows a continuous casting plant 4 in a side view. During the casting process, the strand transfers heat to the strand rollers or the surroundings. The heat discharge between the strand rollers is transferred to TEG modules 5. For this purpose, the TEG modules 5 are arranged between the strand rollers. The TEG modules 5 transfer the produced current through heat insulated, moisture-protected cable 6 at the voltage transformers or inverters 7 which, after adjustment, feed the current into the power supply 8. The aforementioned devices are only schematically illustrated in FIG. 2. Moreover, this Figure also shows the area behind the continuous casting plant 4 which is provided, as illustrated, for avoiding heat losses with roller table covers 9.

Following the continuous casting plant 4, is also arranged a flame cutting plant 10 for cutting slabs to length. The TEG modules are cooled. For this purpose cooling water lines 11 are provided which lead to a cooling unit 12 (particularly to a cooling tower).

Details of this embodiment, in which heat of the cast strand is picked up and conducted further for the purpose of recuperating energy through TEG modules to a current generating plant, are illustrated in FIGS. 3a and 3b, respectively. The Figures only show a section of the continuous casting plant consisting of three segment rollers 13.

In the illustrated example, the radiated heat of the cast strand 1 is initially fed to a heat exchanger plate 14. This constitutes the warm side of the TEG module 5. Through heat lines the heat is transferred to the plate-shaped TEG modules 5. The cooling 15 is arranged on the other side of the TEG module 5. Water of the already existing strand shell cooling unit is used for cooling. The cooling medium is conducted toward the outside through the cooling line 60. By applying this temperature difference, electrical current is produced in the TEG module 5 wherein the current is conducted to the outside through a cable 6 which is resistant to water, steam and heat. Details, such as electrical insulation, protection of the TEG module against water and steam, are not shown in the Figures. A plate heat exchanger can be used as cooling 15, wherein the heat exchanger has several bores through which a cooling medium (for example water) circulates. It is also possible to provide a cooling chamber which is preferably equipped with cooling ribs 17. The lateral fastening means of the TEG modules 5 to the corresponding components are not illustrated.

If, alternatively or simultaneously, an external strand cooling (not illustrated) should be necessary, it is also possible to carry out a combined or alternative use of an existing spray cooling together with the TEG modules 5 which are protected against moisture if it is no longer necessary for metallurgical reasons for influencing the slab temperature.

Another alternative structural embodiment for receiving the heat of the cast strand is illustrated in FIG. 4a in a front view and in FIG. 4b in a side view. The Figures show a small section of a continuous casting plant half, composed of three segment rollers which are illustrated in FIG. 4a in broken lines, as well as the cast strand indicated in dash-dot lines. In this case, heat exchangers 18 are utilized through which gaseous medium 19 (for example air) is conducted. The radiation heat of the cast strand 1 is transferred to the heat exchanger plate of the gas duct and is received by the gaseous medium 19. Ribs 20 and turbulence plates in the gas duct increase the convective heat transfer. The side of the heat exchanger 18 which faces the slabs is constructed with thermal insulation. This insulating cassette reduces the heat losses. By means of one or more blowers 21 the gaseous medium is conveyed from the heat exchangers through gas transporting lines to one or more TEG modules outside or next to the continuous casting plant. These gas transporting lines are constructed as ring lines and are provided with thermal insulation 22.

In the heat exchanger duct 23 is located a heat exchanger unit 24 consisting of the hot air duct, the TEG module, and cooling ducts for the water cooling system, which are constructed in layers.

The temperature of the gaseous medium 19 following the neat exchanger unit (TEG module unit) 24, is adjusted in dependence on the desired strand cooling as well as the requirements of the current production plant or other objectives. Used as the adjusting member is the volumetric flow of the blower 21. The temperature of the air 19 is measured by means of a temperature sensor 25.

The TEG unit absorbs the heat of the gaseous medium 19. As mentioned, the heat exchanger unit 24 is composed of hot air ducts through which the air 19 flows, as well as of TEG modules and cooling ducts. These structural components are mounted in layers within the pipe, so that respectively between the TEG modules a temperature difference is created and current is produced efficiently as a result.

Alternatively, also in the pipe with internal ribs, a plurality of TEG modules may be fastened to the pipe wall and cooling of the TEG modules may take place externally.

In FIG. 5, slab storage 26 is illustrated in a top view. From the continuous casting plant, the slabs are transported through roller conveyors 27 which are thermally insulated or constructed with TEG modules into the slab storage 26. In the slab storage 26, optionally a portion of the storage locations are constructed as reservoir-type storage locations with TEG modules 28, while the remaining storage locations are conventional storage locations 29. Depending on the slab temperature which is still present and the cooling progress, also in this case, an exchange of the slabs controlled by a process model between the normal storage locations and the reservoir-type storage locations takes place. The stabs cooled on the conventional storage locations and the slabs cooled on the reservoir-type storage locations are then removed for further processing from the slab storage 26 controlled by the process model and conveyed through heating furnaces 30 in the transport direction F to the rolling train. The slab sorting and planning model and the process model for optimizing the energy production are coupled to each other. The energy produced in the reservoir-type storage locations is discharged to the outside and is fed as current into the power supply. The further schematic construction is similar to the one discussed in FIG. 2.

FIG. 5 also shows the heating furnaces 30 with the corresponding waste as ducts 59. Within the waste gas ducts or/and pipe walls, thermogenerator modules are provided for energy recuperation (details not illustrated). The thermogenerator modules within the waste gas ducts are constructed analogous to the heat exchanger unit 24.

Details concerning the heat recuperation during transportation of the slab on a roller table 31 with rollers 32 are illustrated in various alternatives in the side view of FIG. 6. TEG modules are arranged between the rollers 32 of the roller gable and along the roller table 31. The TEG modules on the upper side can be integrated in a holding device 33. The principle of the current production by means of supplied radiation heat and transfer to a cooling medium corresponds to the above description. On the bottom side, the embodiments have been varied in order to demonstrate the various possibilities. In particular, the cooling 15 (cooling unit) can be composed of a plate with bores (bottom left in FIG. 6), or of a cooling chamber, preferably with ribs (bottom center in FIG. 6). As cooling medium, water or air can be used. The TEG module 5 can be constructed on the side facing the slabs with a heat exchanger plate 14 or so as to be self-supporting, (without heat exchanger plate) (bottom right in FIG. 6).

In the case of a longer structural length of the roller table with combined TEG modules 5 according to FIG. 6, gaps are provided between the units, so that the slabs 1 can be removed (pushed out, lifted, up) for logistical reasons or for roller program planning, etc. from the heat recuperation line.

The radiation heat and convection is denoted by 34.

FIG. 7 shows in a sectional side view a reservoir-type storage location 28 in the aforementioned slab storage 26. Here a slab 1 can be stored individually, or—as illustrated—a stack of slabs can be stored. On the upper side is mounted a pivotable or movable hood 35 which facilitates slab handling. The stack of slabs is surrounded by TEG modules 5.

Optionally, it is also possible to arrange only TEG modules on the bottom side and to place a heating hood thereabove. As already described, the energy radiated by the slabs 1 is transferred to the TEG modules 5 for current production. The cooling water transport direction is denoted by R. The stack of slabs rests on support rails 36 which, in turn, are arranged on a base plate 37.

A typical preferred embodiment for the arrangement of several reservoir-type storage locations next to each other is illustrated in the form of a holding pit 38 shown in FIG. 8a in a top view and in FIG. 8b in a side view. The slabs 1 rest in the longitudinal direction on support rails 36. By means of slidable ceiling plates 39, the slabs 1 can be removed here individually. The shunting place for the movable hood 35 is denoted by 40. Alternatively, the ceiling plates 39 can also be swung up individually. TEG modules 5 (see FIG. 8b) are arranged on the floor, on the walls, and optionally also on the ceiling. In addition, TEG modules 5 can also be arranged between the slab stacks (not illustrated), which are subjected to radiation from both sides and have the cooler in the middle. Instead of discharging the energy into the surroundings through enforced convection, it is transferred to the TEG modules 5. The connecting lines to the cooling plant and the current producing plant are not illustrated.

In order to influence the convective heat transfer in dependence on the material, of the slab stack height, and of the temperature level, an air flow is produced within the pit 38 by means of temperature resistant ventilators 21. This makes it possible to simultaneously influence the cooling speed and temperature distribution in the pit. If the heat transfer from the slabs 1 to the TEG modules 5 is to be reduced, i.e., for example, in certain slab materials, an extremely low cooling speed is desired, it is also provided that the TEG modules 5 can be partially blocked or lined by means of ceramic plates, not illustrated, having a defined thickness.

Instead of arranging TEG modules 5 around the stack of slabs, the slabs 1 can be stored in an insulated space (for example holding pit), through which a gaseous medium (for example air) flows through a ring line, as it is illustrated in the embodiment in FIG. 9. In this case, a forced flow is generated by means of a blower 21 through the slab storage space, through the heat exchanger duct 23 or several smaller tubular ducts and back. Alternatively, in special cases, the waste air can also be conducted in a chimney with heat exchangers. However, the ring line avoids waste air heat losses. In the ring line, for example, the air 19 transfers the heat energy to TEG module unit or heat exchanger unit 24 (comprising the hot air duct, the TEG module 5 and the cooling ducts for the water cooling, preferably in layers).

The slab storage space may be constructed in the form of a holding pit or may be arranged on ground level. AS illustrated in FIG. 9, several slab stacks or also individual slab stacks—in special cases single slabs 1—in a space through which a gaseous medium 19 (for example air, smoke gas, nitrogen) is blown separately in a ring line.

In order to increase the convective heat transfer from the slab 1 or slab stack to the air 19, radiation plates (not shown) can be mounted next to the stacks or as wall lining. The radiation plates absorb the radiation energy of the slabs and are heated and increase the heat exchanger surface area for the convective heat transfer to the circulating gaseous medium 19 (for example air) and increase the efficiency in this manner.

Particularly advantageously, the cooling speed of the slabs can be controlled by means of the blower 21 as the adjusting unit. Moreover, an adjustment of the blower output in dependence on the slab temperature is possible. Additionally, the temperature of the gaseous medium 19 behind the TEG modules 5 can be adjusted in dependence on the conditions or limitations of the TEG plant or other objectives.

In FIGS. 10a and 10b, a high slab storage shelf 41 is illustrated in a sectional front view and a sectional side view, in which storage is made possible which is as compact and inexpensive as possible. The slabs 1 are pushed flat laterally in filling direction S into the reservoir-type storage locations 42, for example, by means of a stacker (not illustrated), for which purpose the high slab storage shelf is constructed with lateral doors 43 which, are slidable in sections. Within the high slab storage shelf 41, the slabs 1 rest on support rails 36. TEG modules 5 are integrated in or in front of the walls and ceilings, so that the supporting members of the construction are not heated too much and the stability is maintained. In the middle area TEG modules can be arranged between the slabs (center walls) on both sides around a cooling system. In other words, the inner walls can be constructed in layers of the combination of heat exchanger plate/TEG module/cooling/TEG module/heat exchanger plate.

Details of the TEG modules etc. cannot be seen in FIGS. 10a, b.

An alternative possibility of storing the slabs resides in storing the slabs 1 in reservoir-type storage locations of an on edge slab storage 44. In FIG. 11a, such an on edge storage shelf is shown in a top view and in FIG. 11b in a sectional front view. For storage, the slabs 1 are tilted, placed on their wide side, and are then pushed on edge from the side into the reservoir-type storage locations 42 of the on edge slab storage 44. The filling direction S is indicated in FIG. 11a with an arrow. Because of the greater packing density of the on edge storage with TEG modules 5 arranged between the slabs 1, an intensive heat transfer takes place from the slabs 1 to the TEG modules 5. In order to counteract the energy losses, a movable thermally insulated, door 43 is provided which can be displaced in the transport direction as necessary. The slabs 1 which have been placed on edge rest, for example, on rollers 45 or otherwise constructed supports which facilitate a lateral moving of the slabs into and out of the on edge slab storage 44. For the lateral guidance and tilting safety of the slabs, lateral supports 46, for example, rollers also in this case, are arranged next to the TEG modules 5, wherein the rollers also facilitate an easier in and out displacement of the slabs 1. The TEG modules 5 with appropriate cooling 15 and cables and pipes are only illustrated schematically and are arranged analogously to the previously illustrated embodiments.

FIG. 12 shows coil storage 47 in a top view. The coils produced by a reel 48 are transferred through a coil transport line 49, which may be surrounded by TEG modules or constructed with thermally insulating hoods, to their storage locations. These storage locations are partially constructed as reservoir-type storage locations with TEG modules 50, with the remainder being conventional coil storage locations without TEG modules 51. Depending on the remaining temperature and the cooling progress of the coils, an exchange of the coils between the storage locations and the reservoir-type storage locations takes place controlled by the process model. The TEG modules placed in the reservoir-type storage locations are not illustrated here.

In approximately the same manner as the slabs in the embodiment of FIGS. 10a and 10b, the coils can be stored in a high coil storage shelf 52 for cooling and current production, as it is illustrated in FIG. 13a in a sectional front view and 13b in a sectional side view. The illustrated coil or the high coil storage shelf 52 does not differ structurally from the high storage shelf for slabs, so that the respective reference characters can be transferred to the high coil storage shelf 52, wherein the coils are denoted by 53. Compared to the high slab storage shelf, in the high coil storage shelf 52 there is the option that the illustrated coil compartments 54 are arranged laterally offset relative to each other for reasons of stability, and that, in addition to a rectangular construction of the coil compartments 54, for example, a hexagonal construction, is also possible. Also, in this case the floors, walls, and ceilings, composed of the supporting structures and the TEG modules are only schematically illustrated.

A process model for controlling the entire process of converting the residual heat within the continuous casting plant and from slabs 1 or coils 53 into electric energy, including the required slab handling is illustrated in FIG. 14 in connection with the example of cooling of slabs 1. On a roller table 31, hot slabs 1 are transported from the continuous casting plant 4 or a flame cutting plant 10 to the slab storage 26 and are placed there onto reservoir-type storage locations with TEG modules (corresponding, for example, to FIG. 7). After cooling has been carried out, the cooled slabs 1 are then removed from the slab storage 26 and placed on other slab storage locations without TEG modules or are convoyed in the transport direction F to the rolling train. The produced current is conducted to the voltage converters 7 and fed into the current supply.

The slab information 56 (slab input) as well as the information concerning the reservoir-type storage locations or TEG module locations 57 (reservoir location input) are supplied to the process model 55 through appropriate signal lines 58:
Slab input: Slab tonnage, slab geometry, slab temperature (measured, computed), casting speed;
Reservoir-type storage location: Measured entry and exit temperature of the cooling medium of the TEG module for every reservoir-type storage location.

From this information, process parameters are computed in the process model 55 and are used through appropriate control lines for controlling the slab handling. In particular, the following computations are carried out:
Computation of the slab temperatures and combination with the slab sorting and storage system.
Optimizing the slab exit temperature in dependence on the reservoir-type storage locations.
Computing the temperature of the slabs in the reservoir-type storage locations.
Determining pump capacity or adjusting the switching valves for each TEG reservoir-type storage location with TEG cooling in dependence on the slab temperature and determining, depending thereon, whether a slab is placed in the reservoir-type storage location.
Computing the total heat flow and current quantity produced.
Predetermining the casting speed in the continuous casting plant.
Determining the discharge time of the slabs from the reservoir-type storage locations.

### LIST OF REFERENCE NUMERALS

1 Slab/billet/cast strand/coil (product) block/girder/round steel
2 Thermocouple element (thermoelectric generator-TEG)
3 Water cooling
4 Continuous casting plant
5 TEG module
6 Cable
7 Voltage transformer/inverters
8 Power supply
9 Roller table cover
10 Flame cutting plant
11 Cooling water line
12 Cooling
13 Segment roller
14 Heat exchanger plate or protective plate
15 Cooling
16 Cooling line
17 Cooling rib
18 Heat exchanger
19 Gas (air/nitrogen/smoke gas)
20 Rib
21 Blower/ventilator
22 Thermal insulation
23 Heat exchanger duct
24 Heat exchanger unit
25 Temperature sensor
26 Slab storage
27 Supply roller table
28 Reservoir-type storage location with TEG module
29 Storage location
30 Holding furnace
31 Roller table
32 Roller table roller
33 Support device for the current production unit
34 Radiation heat and convection
35 Hood (pivotable, movable)
36 Support rail
37 Base plate
38 Holding pit
39 Ceiling plate
40 Shunting location
41 High slab storage shelf
42 Reservoir-type storage location.
43 Door (movable, thermally insulated)
44 On edge slab storage
45 Roller
46 Support
47 Coil storage
48 Reel
49 Coil transport line
50 Coil storage location with TEG module
51 Coil storage location without TEG module
52 High coil storage shelf
53 Coil
54 Coil compartment
55 Process model
56 Slab information
57 Reservoir-type storage location information
58 Signal or control line
59 Waste gas duct of the holding furnace
dQ/dt Heat flow
T₁ Temperature
T₂ Temperature
F Transport direction
R Cooling water transport direction
S Filling direction

1. Method for energy recuperation in metallurgical plants utilizing residual heat of a plant component and/or hot product (1),
characterized in that
a heat flow dQ/dt is allowed to flow from a plant component and/or hot product (1) having a first temperature level T₁ to a location having a second lower temperature level T₂, wherein, between the two temperature levels T₁, T₂, at least one thermocouple element (2) is arranged which directly produces electrical energy by utilizing the heat flow dQ/dt.

2. Method according to claim 1, characterized in that as thermocouple element (2), a thermocouple element with at least one doped semiconductor pair is used.

3. Method according to claim 1 or 2, characterized in that thermocouple element (2), a thermocouple element is used which is coated by means of the PVD method (Physical Vapor Deposition) and is subsequently mechanically manufactured.

4. Method according to one of claims 1 to 3, characterized in that the at least one thermocouple element (2) is utilized in a temperature range of 100° C.-120° C., and the material of the thermocouple element (2) is optimally adjusted to the respective temperature.

5. Method according to one of claims 1 to 4, characterized in that a number of thermocouple elements (2) are used which are switched together to form thermoelectric generator (TEG).

6. Method according to one of claims 1 to 5, characterized in that initially a slab (1) is continuously cast in a continuous casting plant (4) and that following the continuous casting plant (4), the slab (1) is cut to length by means of a severing device (10), particularly a flame cutting machine, wherein the slab (1) is protected against heat discharge in front of and/or behind the severing device (10) by thermal insulation means.

7. Method according to claim 6, characterized in that thermal insulation means (35) constructed as thermal insulation hoods are positioned in such a way that their position is adapted to the actual slab size and/or the conditions when cutting the slab (1).

8. Method according to claim 6 or 7, characterized in that the cut slab (1) is transported into slab storage (26) in the longitudinal or transverse directions, wherein the transport takes place on a roller table which is surrounded at least partially by thermocouple elements (2) or thermoelectric generators.

9. Method according to claim 8, characterized in that the slab (1) is transported and allowed to cool between the continuous casting plant (4) and the slab storage (26) in such a way that it reaches or does not drop below a predetermined temperature.

10. Method according to one of claims 1 to 9, characterized in that at least one thermocouple element (2) is cooled on at least one side.

11. Method according to one of claims 1 to 10, characterized in that the residual heat of the hot product (1), which has not been converted into electrical energy by means of the thermocouple element (2), is utilized in another process which requires heat.

12. Method according to one of claims 1 to 11, characterized in that the heat of the cooling medium of the TEG element is utilized for drying a substance, for sea water desalination, for heating a device, or for chemical processes.

13. Method according to one of claims 1 to 12, characterized in that the method for producing current by means of thermocouple elements and/or by means of a thermoelectric generator is combined with other energy recuperating technologies, preferably circulation processes (ORC plant/Kalina plant), for further current production.

14. Metallurgical plant, comprising a plant part and/or a hot product (1) having a first temperature level T₁ as well as a location having a second, lower temperature level T₂, characterized in that
in the area between the plant component and/or the hot product (1) having the first temperature level T₁ and the location with the second temperature level T₂ is arranged at least one thermocouple element (2) for the direct production of electrical energy by utilizing the heat flow (dQ/dt) resulting from the temperature gradient.

15. Plant according to claim 14, characterized in that the thermocouple element (2) has at least one doped semiconductor pair.

16. Plant according to claim 14 or 15, characterized in that the thermocouple element (2) is manufactured by means of the PVD method (Physical Vapor Deposition).

17. Plant according to one of claims 14 to 16, characterized in that a number of thermocouple elements (2) are switched together to form a thermoelectric generator (TEG) (5).

18. Plant according to one of claims 14 to 17, characterized in that it is, or comprises, a continuous casting plant (4) and/or furnaces and/or a hot strip rolling train.

19. Plant according to one of claims 14 to 18, characterized in that thermocouple elements and/or thermoelectric generators are arranged between and/or adjacent the strand rollers of the continuous casting plant or adjacent the continuous casting plant.

20. Plant according to one of claims 14 to 19, characterized in that it comprises a furnace (30) which has thermogenerator modules within the exhaust gas ducts 59 or/and at the pipe or duct walls.

21. Plant according to one of claims 14 to 20, characterized in that a transport path, particularly a roller table on which no thermocouple elements (2) are arranged is provided with thermal insulation means.

22. Plant according to one of claims 14 to 21, characterized, in that a transport path, particularly a roller table, or the transported product (for example, slab, billet or coil), and is surrounded by thermocouple elements or thermoelectric generators.

23. Plant according to one of claims 14 to 22, characterized in that it comprises slab storage (26) and/or coil storage (47) whose walls have thermocouple elements (2) and/or thermal insulation means.

24. Plant according to claim 23, characterized in that the thermocouple elements (2) and/or the thermal insulation means are arranged so as to be movable, particularly pivotable or translatory slidable.

25. Plant according to claim 23 or 24, characterized in that air revolving means (21), particularly at least one blower, are arranged in the slab or coil storage.

26. Plant according to one of claims 23 to 25, characterized in that the energy is transported to the heat exchanger unit (24) and/or to the thermoelectric generators, and is transferred there in a concentrated manner through a ring line from the product (1) or storage (26, 47) by means of a gaseous heat transporting medium (air, smoke gas, nitrogen) and at least one blower.

27. Plant according to claim 25 or 26, characterized in that the throughput of the gaseous heat transport medium and, thus, the energy exchange, are controlled by means of the blower.

28. Plant according to one of claims 23 to 27, characterized in that the slab or coil storage is constructed as a holding pit or high storage shelf, or mill or mill, level.

29. Plant according to one of claims 14 to 28, characterized in that cooling means are arranged for cooling at least one side of the thermocouple element (2).

30. Plant according to one of claims 14 to 29, characterized in that several thermoelectric generators are arranged stacked in a heat exchanger unit (24), wherein especially the heating medium, the thermocouple element or thermoelectric generator, and the cooling medium act alternately or are arranged alternately.

31. Plant according to claim 29 or 30, characterized in that the cooling means are constructed for operation with air, nitrogen, smoke gas, water or a medium which boils at high temperatures, particularly thermoil.
